(19) United States
(12) Patent Application Publication
(10) Pub. No.: US 2024/0363710 A1
(43) Pub. Date: Oct. 31, 2024

(54) SEMICONDUCTOR DEVICE

(71) Applicant: ROHM CO., LTD., Kyoto-shi (JP)

(72) Inventor: Kenta WATANABE, Kyoto-shi (JP)

(73) Assignee: ROHM CO., LTD., Kyoto-shi (JP)

(21) Appl. No.: 18/641,457

(22) Filed: Apr. 22, 2024

(30) Foreign Application Priority Data
Apr. 26, 2023 (JP) 2023-072094

(51) Int. Cl. H01L 29/423; H01L 29/40; H01L 29/417; H01L 29/78

(52) U.S. Cl. CPC H01L 29/4236; H01L 29/407; H01L 29/41741; H01L 29/7813

(57) ABSTRACT

The present disclosure provides a semiconductor device. The semiconductor device includes: a first gate trench and a second gate trench, arranged along a first direction in a plan view seen from a direction perpendicular to the upper surface, and extending along a second direction intersecting the first direction; a third gate trench, extending along the first direction from the first gate trench toward the second gate trench and forming a first gap with the second gate trench; a fourth gate trench, spaced apart from the third gate trench along the second direction, extending along the first direction from the second gate trench toward the first gate trench and forming a second gap with the first gate trench; a field plate trench, disposed in a cell region surrounded by the first to fourth gate trenches; and gate electrodes, disposed within the first to fourth gate trenches.

### CROSS-REFERENCE TO RELATED APPLICATION

This application is based upon and claims the benefit of priority from Japanese Patent Application No. 2023-072094, filed on Apr. 26, 2023, the entire contents of which are incorporated herein by reference.

### TECHNICAL FIELD

The present disclosure relates to a semiconductor device.

### BACKGROUND

Patent document 1 discloses a MISFET having a trench gate structure. The trench gate structure includes a gate trench, an insulating layer, a bottom side electrode and an opening side electrode. Patent document 1 describes that by applying a reference voltage to the bottom side electrode and applying a gate voltage to the opening side electrode, a switching speed can be improved while suppressing a decrease in a withstand voltage of the MISFET.

### PRIOR ART DOCUMENT

### Patent Publication

[Patent document 1] Japan Patent Publication 2020-072158

### BRIEF DESCRIPTION OF THE DRAWINGS

FIG. 1 is a schematic plan view of an exemplary semiconductor device.

FIG. 2 is a schematic plan view illustrating a gate trench and a field plate trench of the semiconductor device of FIG. 1.

FIG. 3 is an enlarged schematic plan view of a portion of the semiconductor device of FIG. 1.

FIG. 4 is a schematic cross-sectional view taken along line 4-4 in FIG. 3.

FIG. 5 is a schematic cross-sectional view taken along line 5-5 in FIG. 3.

FIG. 6 is a schematic plan view for explaining the number of current paths and cross sections of the current paths in a unit cell of the semiconductor device of FIG. 1.

FIG. 7 is a schematic plan view for explaining the number of current paths and cross sections of the current paths in a unit cell of a semiconductor device of a comparative example.

FIG. 8 is a schematic cross-sectional view taken along line 8-8 in FIG. 7.

FIG. 9 is a schematic plan view showing a unit cell of a semiconductor device according to a modified example.

FIG. 10 is a schematic cross-sectional view taken along line 10-10 in FIG. 9.

FIG. 11 is a schematic cross-sectional view taken along line 11-11 in FIG. 9.

FIG. 12 is a schematic plan view showing a portion of a semiconductor device according to a modified example.

FIG. 13 is a schematic plan view showing a portion of a semiconductor device according to a modified example.

### DETAILED DESCRIPTION OF THE EMBODIMENTS

Hereinafter, some embodiments of the semiconductor device of the present disclosure will be described with reference to the accompanying drawings. It should be noted that, for simplicity and clarity of explanation, the components shown in the drawings are not necessarily drawn to scale. Furthermore, in order to facilitate understanding, hatching lines may be omitted in the cross-sectional views. The accompanying drawings are merely illustrative of embodiments of the disclosure and should not be considered as limiting the disclosure.

Terms such as “first”, “second” and “third” in the present disclosure are used merely to distinguish between objects, and are not intended to rank the objects. In addition, “parallel”, “perpendicular”, “orthogonal” and “constant” in this specification do not mean strictly parallel, perpendicular, perpendicular or fixed, but generally within the range that produces the effects of this embodiment. This includes parallel, perpendicular, perpendicular and constant cases. In the specification, “equal” includes not only exact equality but also cases where there is some difference between comparison targets due to dimensional tolerances and the like.

The detailed description below includes devices, systems, and methods that embody example embodiments of the present disclosure. This detailed description is illustrative in nature and is not intended to limit the embodiments of the disclosure or the application and uses of such embodiments.

The expression “at least one” as used herein means “one or more” of desired options. As an example, the expression “at least one” as used herein means “only one option” or “both of the two options” if the number of options is two. As another example, the expression “at least one” as used herein means “only one option” or “a combination of two or more options” if there are three or more options.

### (Schematic Configuration of a Semiconductor Device)

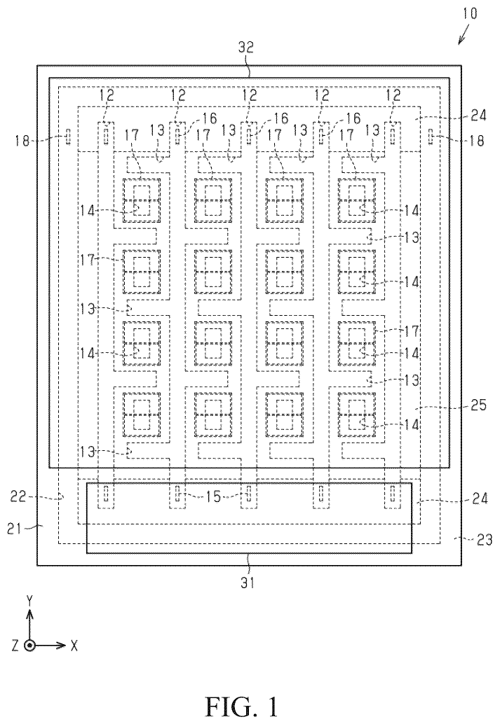

FIG. 1 is a schematic plan view of an exemplary semiconductor device 10 according to a first embodiment. Note that the term “plan view” used in the present disclosure refers to viewing the semiconductor device 10 along the Z-axis direction of mutually perpendicular XYZ axes shown in FIG. 1. Unless explicitly stated otherwise, “plan view” refers to viewing the semiconductor device 10 from above and along the Z-axis.

The semiconductor device 10 is, for example, a MISFET having a split gate structure. The semiconductor device 10 includes a semiconductor layer 11. The semiconductor layer 11 can be formed from, for example, silicon (Si). The semiconductor layer 11 includes an upper surface 11A and a lower surface 11B opposite to the upper surface 11A. The semiconductor layer 11 has a thickness along a direction perpendicular to the upper surface 11A (Z-axis direction).

The semiconductor device 10 includes multiple gate trenches 12. In one example, the gate trenches 12 extend along the Y-axis direction in a plan view. The gate trenches 12 have a width along the X-axis direction. The gate trenches 12 are arranged along the X-axis direction in the plan view. The gate trenches 12 may be arranged at equal intervals along the X-axis direction in the plan view.

Furthermore, the semiconductor device 10 includes multiple gate trenches 13. The gate trenches 13 extend along the X-axis direction in the plan view. The gate trenches 13 have a width along the Y-axis direction. The gate trenches 13 are arranged that each of two gate trenches 12 adjacent to each other along the X-axis direction. Furthermore, the gate trenches 13 are arranged along the Y-axis direction. The gate trenches 13 may be arranged at equal intervals along the Y-axis direction in the plan view.

Note that FIG. 1 shows an example of an arrangement of the gate trenches 12 and 13 in the semiconductor device 10. The arrangement of the gate trenches 12 and 13 may be changed. For example, the semiconductor device 10 may include multiple gate trenches 12 arranged along the Y-axis direction. Furthermore, the semiconductor device 10 may include multiple rows of gate trenches 12. The gate trenches 13 are arranged according to the arrangement of the gate trenches 12.

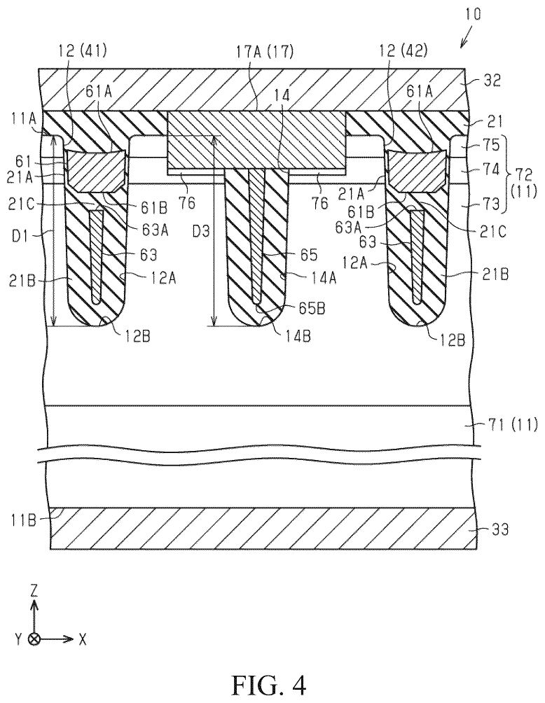

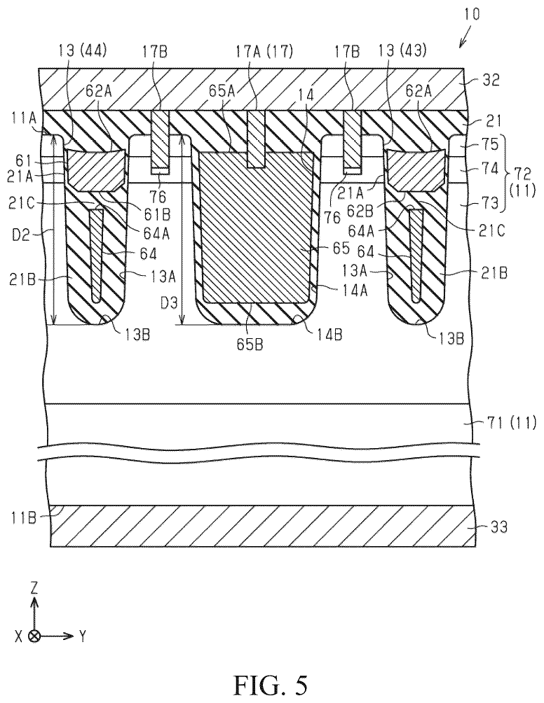

Gate electrodes 61 and 62 and field plate electrodes 63 and 64 (see FIGS. 4 and 5), which will be described later, can be arranged in the gate trenches 12 and 13. The gate trenches 12 and 13 have an opening in the upper surface 11A of the semiconductor layer 11 and have a depth along the Z-axis direction. In this specification, the Z-axis direction is also referred to as “a depth direction of the gate trenches 12 and 13,” the X-axis direction is also referred to as “a first direction,” and the Y-axis direction is also referred to as “a second direction.” Therefore, the depth direction of the gate trenches 12 and 13 is perpendicular to both the first direction and the second direction, and the second direction is perpendicular to the first direction in the plan view.

The semiconductor device 10 further includes a field plate trench 14 formed in the semiconductor layer 11. The field plate trench 14 is arranged between the gate trenches 12 and 13. Furthermore, the field plate trench 14 is spaced apart from the gate trenches 12 and 13. That is, the field plate trench 14 does not communicate with the gate trenches 12 and 13. In one example, the field plate trench 14 extends along the Y-axis direction in the plan view. The field plate trench 14 is formed in a rectangular shape having a width along the X-axis direction.

The semiconductor device 10 includes an insulating layer 21 formed on the semiconductor layer 11. The insulating layer 21 is in contact with the upper surface 11A of the semiconductor layer 11. The insulating layer 21 can be formed from a silicon oxide film (SiO₂), for example. The insulating layer 21 may additionally or alternatively include a layer formed from an insulating material different from SiO₂, such as silicon nitride (SiN).

The semiconductor device 10 may further include a peripheral trench 22 formed in the semiconductor layer 11. The peripheral trench 22 can be arranged to surround the gate trenches 12 and 13 in the plan view while being separated from the gate trenches 12 and 13. A peripheral electrode (not shown) can be disposed within the peripheral trench 22.

As shown in FIG. 1, the upper surface 11A of the semiconductor layer 11 can include an n⁻ type region 23 containing n-type impurities, a p⁻ type region 24 containing p-type impurities and an n⁺ type region 25 containing n-type impurities. The n⁻ type region 23 may surround the peripheral trench 22. Furthermore, the p⁻ type region 24 and the n⁺ type region 25 may be surrounded by the peripheral trench 22. Because the peripheral trench 22 is present, a p-n junction interface between the p⁻ type region 24 and the n⁺ type region 25 is not exposed, so that a breakdown voltage of the semiconductor device 10 can be improved.

The gate trenches 12 and 13 can be disposed adjacent to both p type region 24 and the n⁺ type region 25. In the example of FIG. 1, the n⁺ type region 25 can be located between two p-type regions 24 along the Y-axis direction. Each end of the gate trench 12 along the Y-axis direction can be adjacent to one of the two p-type regions 24. On the other hand, an intermediate portion of the gate trench 12 can be adjacent to the n⁺ type region 25. The gate trench 13 may be adjacent to the n⁺ type region 25.

The semiconductor device 10 can further include a gate electrode 31 and a source electrode 32 formed on the insulating layer 21. Each of the gate electrode 31 and the source electrode 32 can be disposed to cover portions of the gate trenches 12, 13 and a portion of the peripheral trench 22. The gate electrode 31 can be arranged to at least partially overlap one of the two p-type regions 24. The source electrode 32 can be arranged to at least partially overlap the other of the two p-type regions 24. The source electrode 32 may cover at least the entire n⁺ type region 25 while being separated from the gate electrode 31.

The gate electrode 31 and the source electrode 32 can be formed from at least one of titanium (Ti), nickel (Ni), gold (Au), silver (Ag), copper (Cu), aluminum (Al), Cu alloy, and Al alloy.

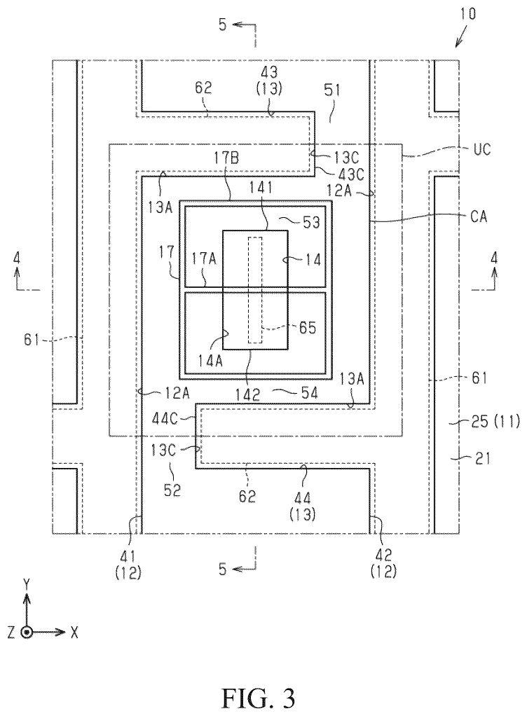

The semiconductor device 10 can further include a plurality of gate contacts 15. Each gate contact 15 can connect the gate electrodes 61 and 62 (see FIG. 3) disposed within each gate trench 12 and 13 to the gate electrode 31. The gate contact 15 can extend along the Z-axis direction so as to penetrate the insulating layer 21 located between the gate electrodes 61 and 62 and the gate electrode 31 in the gate trenches 12 and 13. In one example, the gate contact 15 can be arranged in a region where the gate trench 12 and the gate electrode 31 overlap in the plan view.

The semiconductor device 10 can further include a plurality of source contacts 16. Each source contact 16 can connect the field plate electrodes 63 and 64 (see FIGS. 4 and 5) disposed within each gate trench 12 and 13 to the source electrode 32. The source contact 16 can extend along the Z-axis direction so as to penetrate the insulating layer 21 located between the field plate electrodes 63 and 64 and the source electrode 32. In one example, the source contact 16 can be disposed in a region where the gate trench 12 and the source electrode 32 overlap in the plan view.

The semiconductor device 10 can include a plurality of source contact plugs 17. The source contact plug 17 can be disposed in a region surrounded by the gate trenches 12 and 13. The source contact plug 17 can connect a contact region 76 formed in the semiconductor layer 11 to the source electrode 32. The source contact plug 17 can extend along the Z-axis direction so as to penetrate the semiconductor layer 11 and the insulating layer 21 located between the contact region 76 and the source electrode 32.

The source contact plug 17 may be formed to surround the field plate trench 14 arranged between two gate trenches 12 adjacent along the X-axis direction. Furthermore, the source contact plug 17 connects a field plate electrode 65 (see FIGS. 3 to 5) arranged in the field plate trench 14 to the source electrode 32.

Semiconductor device 10 may further include one or more contacts 18 connecting a peripheral electrode (not shown) disposed within the peripheral trench 22 to the source electrode 32. The gate contact 15, the source contact 16, the source contact plug 17, and contact 18 can be formed from any metal material. In one example, the gate contact 15, the source contact 16, the source contact plug 17, and contact 18 may be formed from at least one of tungsten (W), Ti, and titanium nitride (TiN).

The semiconductor device 10 may include a passivation film covering the gate electrode 31 and the source electrode 32. The passivation film may have openings that expose the gate electrode 31 and the source electrode 32, respectively. In the gate electrode 31, the region exposed through the opening in the passivation film can also be called a gate pad for external connection. In the source electrode 32, the region exposed by the opening in the passivation film can also be called a source pad for external connection.

### (Arrangement of Gate Trench and Field Plate Trench)

An example of the arrangement of the gate trenches 12, 13 and the field plate trench 14 will be described.

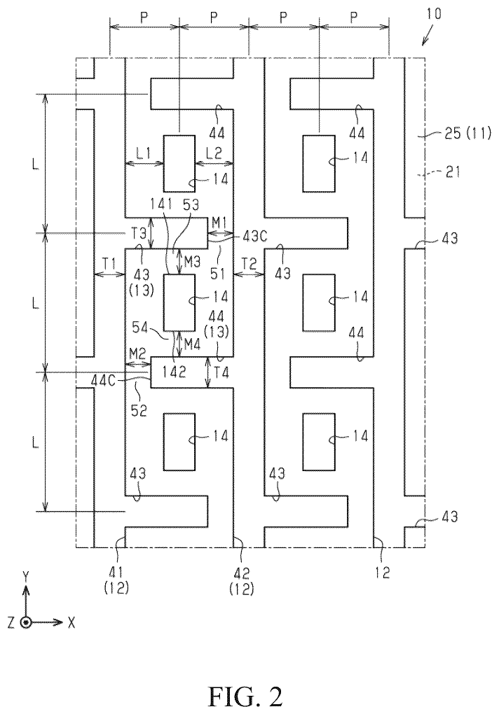

FIG. 2 is a schematic plan view illustrating portions of the semiconductor device 10 of FIG. 1, which shows the gate trenches 12, 13 and the field plate trench 14. In FIG. 2, three gate trenches 12 are shown. One of the plurality of gate trenches 12 is defined as a first gate trench 41, and the gate trench 12 adjacent to the first gate trench 41 along the X-axis direction is defined as a second gate trench 42. In addition, in FIG. 2, the gate trench 12 at the center along the X-axis direction may be used as the first gate trench 41, or the gate trench 12 on the right side of the first gate trench 41 in the drawing may be used as the first gate trench 41. In the following description, when the first gate trench 41 and the second gate trench 42 are not distinguished, the gate trench 12 will be used.

The first gate trench 41 and the second gate trench 42 are arranged side by side along the X-axis direction. The first gate trench 41 and the second gate trench 42 extend along the Y-axis direction intersecting the X-axis direction. The first gate trench 41 and the second gate trench 42 have widths along the X-axis direction. In one example, a trench width of the first gate trench 41 is equal to a trench width of the second gate trench 42. Here, the trench widths of the first gate trench 41 and the second gate trench 42 are defined as a first trench width T1. Note that the trench width of the first gate trench 41 and the trench width of the second gate trench may be different.

The plurality of gate trenches 13 are arranged between the first gate trench 41 and the second gate trench 42. The plurality of gate trenches 13 include: a third gate trench 43 extending along the X-axis direction from the first gate trench 41 toward the second gate trench 42; and a fourth gate trench 44 extending along the X-axis direction from the second gate trench 42 toward the first gate trench 41.

The third gate trench 43 communicates with the first gate trench 41. The third gate trench 43 is spaced apart from the second gate trench 42 along the X-axis direction. The third gate trench 43 forms a first gap 51 between the tip 43C of the third gate trench 43 and the second gate trench 42.

The third gate trench 43 and the fourth gate trench 44 have widths along the Y-axis direction. In one example, a trench width of the third gate trench 43 is equal to a trench width of the fourth gate trench 44. Here, the trench widths of the third gate trench 43 and the fourth gate trench 44 are defined as a second trench width T2. Note that the trench width of the third gate trench 43 and the trench width of the fourth gate trench 44 may be different.

In one example, the second trench width T2 is equal to the first trench width T1. That is, the trench widths of the third gate trench 43 and the fourth gate trench 44 along the Y-axis direction are equal to the trench widths of the first gate trench 41 and the second gate trench 42 along the X-axis direction.

The fourth gate trench 44 is spaced apart from the third gate trench 43 along the Y-axis direction. The fourth gate trench 44 communicates with the second gate trench 42. The fourth gate trench 44 is spaced apart from the first gate trench 41 along the X-axis direction. The fourth gate trench 44 forms a second gap 52 between the tip 44C of the fourth gate trench 44 and the first gate trench 41.

A first length M1 of the first gap 51 is a length from the tip 43C of the third gate trench 43 to the second gate trench 42 along the X-axis direction. A second length M2 of the second gap 52 is a length from the tip 44C of the fourth gate trench 44 to the first gate trench 41 along the X-axis direction. In one example, the first length M1 of the first gap 51 is equal to the second length M2 of the second gap 52. Note that the first length M1 of the first gap 51 and the second length M2 of the second gap 52 may be different.

The plurality of third gate trenches 43 and fourth gate trenches 44 are arranged alternately along the Y-axis direction. In one example, the third gate trench 43 and the fourth gate trench 44 are arranged at equal intervals along the Y-axis direction. Along the Y-axis direction, an arranged pitch between the third gate trench 43 and the fourth gate trench 44 is “L”.

A plurality of field plate trenches 14 are arranged between the first gate trench 41 and the second gate trench 42. The plurality of field plate trenches 14 are arranged along the Y-axis direction. In one example, the plurality of field plate trenches 14 are arranged at equal intervals along the Y-axis direction. The plurality of field plate trenches 14 extend along the Y-axis direction in the plan view. The plurality of field plate trenches 14 are formed in a rectangular shape having a width along the X-axis direction. A width of the field plate trench 14 along the X-axis direction is defined as a trench width T3. In one example, the trench width T3 of the field plate trench 14 is equal to the trench width T3 of the first gate trench 41 and the second gate trench 42. In this example, the trench width T3 of the field plate trench 14 is equal to the trench width T2 of the third gate trench 43 and the fourth gate trench 44.

The field plate trench 14 is arranged between the first gate trench 41 and the second gate trench 42 along the X-axis direction. The field plate trench 14 is arranged between the third gate trench 43 and the fourth gate trench 44 along the Y-axis direction. Therefore, it can be said that the field plate trench 14 is arranged in a cell area CA surrounded by the first gate trench 41, the second gate trench 42, the third gate trench 43 and the fourth gate trench 44. The cell area CA is the semiconductor layer 11 surrounded by the first gate trench 41, the second gate trench 42, the third gate trench 43 and the fourth gate trench 44.

The cell area CA may be included in a unit cell UC defined by the first gate trench 41 and the second gate trench 42 adjacent to each other along the X-axis direction, as well as the third gate trench 43 and the fourth gate trench 44 adjacent to each other along the Y-axis direction. The unit cell UC is defined by an arranged pitch of the gate trenches 12 arranged along the X-axis direction and an arranged pitch of the gate trenches 13 arranged along the Y-axis direction. It can be said that the semiconductor device 10 includes a plurality of unit cells UC. It can be said that the field plate trench 14 is arranged in each unit cell UC.

In one example, the field plate trench 14 is arranged at the center between the first gate trench 41 and the second gate trench 42 along the X-axis direction. Therefore, the first gate trench 41, the field plate trench 14 and the second gate trench 42 are arranged at equal pitches along the X-axis direction. Along the X-axis direction, an arranged pitch between the first gate trench 41 and the field plate trench 14 is “P”. The field plate trench 14 and the second gate trench 42 are arranged at the arranged pitch P. The first gate trench 41 and the second gate trench 42 are arranged at the arranged pitch of 2P. In one example, the arranged pitch L between the third gate trench 43 and the fourth gate trench 44 is equal to the arranged pitch 2P between the first gate trench 41 and the second gate trench 42.

Along the X-axis direction, the first length M1 of the first gap 51 is less than a distance L2 between the first gate trench 41 and the second gate trench 42. The distance L2 between the first gate trench 41 and the second gate trench 42 is determined as a value obtained by subtracting ½ of the first trench width T1 of the first gate trench 41 and ½ of the second trench width T2 of the second gate trench 42 from the arranged pitch 2P of the first gate trench 41 and the second gate trench 42. In one example, the first trench width T1 and the second trench width T2 are equal to each other. Therefore, along the X-axis direction, the first length M1 of the first gap 51 is the difference between the arranged pitch 2P of the first gate trench 41 and the second gate trench 42 and the first trench width T1 (the second trench width T2). It can be said that it is less than the difference. Furthermore, in one example, the second length M2 of the second gap 52 is equal to the first length M1 of the first gap 51. Therefore, it can be said that the second length M2 of the second gap 52 is less than the difference between the arranged pitch 2P between the first gate trench 41 and the second gate trench 42 and the first trench width T1 (the second trench width T2).

Along the X-axis direction, the first length M1 of the first gap 51 may be greater than ⅔ of a distance L1 between the first gate trench 41 and the field plate trench 14. The distance L1 between the first gate trench 41 and the field plate trench 14 is determined as a value obtained by subtracting ½ of the first trench width T1 and ½ of the third trench width T3 of the field plate trench 14 from the arranged pitch P between the first gate trench 41 and the field plate trench 14. In one example, the first trench width T1 and the third trench width T3 are equal to each other. Therefore, along the X-axis direction, the first length M1 of the first gap 51 is the difference between the arranged pitch P between the first gate trench 41 and the field plate trench 14 and the first trench width T1 (=T2=T3). It can be said that it is better to be greater than ⅔. Similarly, along the X-axis direction, the second length M2 of the second gap 52 may be greater than ⅔ of the difference between the arranged pitch P and the first trench width T1 (=T2=T3).

In one example, the field plate trench 14 is arranged at the center between the third gate trench 43 and the fourth gate trench 44 along the Y-axis direction. Therefore, the third gate trench 43, the field plate trench 14 and the fourth gate trench 44 are arranged at equal pitches along the Y-axis direction. Along the Y-axis direction, the distance between the center of the third gate trench 43 and the center of the field plate trench 14 is equal to the distance between the center of the field plate trench 14 and the center of the fourth gate trench 44. These distances are ½ (=L/2) of the arranged pitch L of the third gate trench 43 and the fourth gate trench 44.

The field plate trench 14 is separated from the third gate trench 43 along the Y-axis direction. A third gap 53 is formed between the field plate trench 14 and the third gate trench 43. Furthermore, the field plate trench 14 is spaced apart from the fourth gate trench 44 along the Y-axis direction. A fourth gap 54 is formed between the field plate trench 14 and the fourth gate trench 44.

The field plate trench 14 includes a first end 141 facing the third gate trench 43 and a second end 142 facing the fourth gate trench 44 along the Y-axis direction. The third length M3 of the third gap 53 is the length from the first end 141 of the field plate trench 14 to the third gate trench 43 along the X-axis direction. The fourth length M4 of the fourth gap 54 is the length from the second end 142 of the field plate trench 14 to the fourth gate trench 44 along the Y-axis direction. In one example, the length M3 of the third gap 53 is equal to the fourth length M4 of the fourth gap 54. Note that the length M3 of the third gap 53 and the fourth length M4 of the fourth gap 54 may be different. In one example, the third length M3 of the third gap 53 (the fourth length M4 of the fourth gap 54) is equal to the first length M1 of the first gap 51 (the second length M2 of the second gap 52).

### (Gate Electrode, Field Plate Electrode and Source Contact)

FIG. 3 is an enlarged schematic plan view of a portion of the semiconductor device 10, which shows a region including one unit cell UC.

The semiconductor device 10 further includes the gate electrode 61 embedded in the gate trench 12. The gate electrode 61 extends along the Y-axis direction. The semiconductor device 10 further includes the gate electrode 62 embedded in the gate trench 13. The gate electrode 62 extends along the X-axis direction. The gate electrode 62 buried in the third gate trench 43 is electrically connected to the gate electrode 61 buried in the first gate trench 41. The gate electrode 62 buried in the fourth gate trench 44 is electrically connected to the gate electrode 61 buried in the second gate trench 42.

The semiconductor device 10 includes the field plate electrode 65 embedded in the field plate trench 14. The field plate electrode 65 extends along the Y-axis direction. The source contact plug 17 is arranged in a region surrounded by the gate trenches 12 and 13. The source contact plug 17 includes a first contact 17A formed in a frame shape extending along the X-axis direction, and a second contact 17B formed in a frame shape and connected to both ends of the first contact 17A. The first contact 17A is formed to intersect with the field plate trench 14 and the field plate electrode 65 in the plan view. The second contact 17B is formed to surround the field plate trench 14. In one example, the second contact 17B is formed in the shape of a rectangular frame whose length along the Y-axis direction is greater than its length along the X-axis direction.

### (Cross-Sectional Structure of Semiconductor Device)

FIG. 4 is a schematic cross-sectional view taken along line 4-4 in FIG. 3, and FIG. 5 is a schematic cross-sectional view taken along line 5-5 in FIG. 3.

The semiconductor layer 11 can include a semiconductor substrate 71 including the lower surface 11B of the semiconductor layer 11, and an epitaxial layer 72 formed on the semiconductor substrate 71 and including the upper surface 11A of the semiconductor layer 11. The semiconductor substrate 71 may be a Si substrate. The semiconductor substrate 71 corresponds to the drain region of the MISFET. The epitaxial layer 72 may be a Si layer epitaxially grown on a Si substrate. The epitaxial layer 72 can include a drift region 73, a body region 74 formed on the drift region 73 and a source region 75 formed on the body region 74. The source region 75 can include the upper surface 11A of the semiconductor layer 11. A top surface of the source region 75 corresponds to the n⁺ type region 25 shown in FIG. 1. The epitaxial layer 72 may further include the contact region 76 located under the source contact plug 17.

A drain region 71 (the semiconductor substrate 71) may be an n⁺ type region containing n-type impurities. An n-type impurity concentration of the drain region 71 can be set to be between about 1×10¹⁸ cm⁻³ and about 1×10²⁰ cm 3. The drain region 71 may have a thickness between about 50 μm and about 450 μm.

The drift region 73 may be an n-type region containing n-type impurities having a concentration less than that of the drain region 71. An n-type impurity concentration of the drift region 73 can be set to be between about 1×10¹⁵ cm⁻³ and about 1×10¹⁸ cm⁻³. The drift region 73 may have a thickness between about 1 μm and about 25 μm.

The body region 74 may be a p-type region containing p-type impurities. A p-type impurity concentration of the body region 74 can be set to be between about 1×10¹⁶ cm⁻³ and about 1×10¹⁸ cm⁻³. The body region 74 may have a thickness between about 0.5 μm and about 1.5 μm.

The source region 75 may be an n⁺ type region containing n-type impurities of a concentration greater than that of the drift region 73. An n-type impurity concentration of the source region 75 can be set to be between about 1×10¹⁹ cm⁻³ and about 1×1021 cm⁻³. The source region 75 may have a thickness between about 0.1 μm and about 1 μm.

The contact region 76 may be a p⁺ type region containing p-type impurities. A p-type impurity concentration of the contact region 76 is greater than that of the body region 74, and can be set to be between about 1×10¹⁹ cm⁻³ and about 1×1021 cm⁻³.

Note that in the present disclosure, the n-type is also referred to as a first conductivity type, and the p-type is also referred to as a second conductivity type. The n-type impurity may be, for example, phosphorus (P) or arsenic (As). Furthermore, the p-type impurity may be, for example, boron (B), aluminum (Al), or the like.

### (First and Second Gate Trenches)

As shown in FIG. 4, the gate trench 12 (the first gate trench 41, the second gate trench 42) has an opening in the upper surface 11A of the semiconductor layer 11. The gate trench 12 has a depth D1 along the Z-axis direction. The gate trench 12 extends through the source region 75 and the body region 74 of the semiconductor layer 11 to the drift region 73. The gate trench 12 has sidewalls 12A and bottom walls 12B. Bottom wall 12B is adjacent to the drift region 73. The depth D1 of the gate trench 12 may be between about 1 μm and about 10 μm.

As shown in FIG. 3, the gate trench 12 has a width along the X-axis direction. The gate trench 12 extends along the Y-axis direction. Therefore, the sidewalls 12A of the gate trench 12 face each other along the X-axis direction. It can be said that the sidewall 12A of the gate trench 12 faces the X-axis direction.

As shown in FIG. 4, the sidewall 12A of the gate trench 12 may or may not extend along a direction perpendicular to the upper surface 11A of the semiconductor layer 11 (Z-axis direction). In one example, the sidewall 12A may be inclined with respect to the Z-axis direction so that a trench width of the gate trench 12 becomes less toward the bottom wall 12B.

The semiconductor device 10 can include the gate electrode 61 and the field plate electrode 63 arranged in the gate trench 12. The gate electrode 61 includes a top surface 61A covered with the insulating layer 21 and a bottom surface 61B opposite to the top surface 61A. The field plate electrode 63 is arranged in the gate trench 12 below the bottom surface 61B of the gate electrode 61 (between the bottom surface 61B of the gate electrode 61 and the bottom wall 12B of the gate trench 12). At least a portion of the bottom surface 61B of the gate electrode 61 faces the field plate electrode 63 with the insulating layer 21 in between.

The top surface 61A of the gate electrode 61 can be located below the upper surface 11A of the semiconductor layer 11. The top surface 61A and the bottom surface 61B of the gate electrode 61 may be flat or curved. The gate electrode 61 may or may not have a uniform width regardless of its position along the Z-axis direction. For example, the bottom portion of the gate electrode 61 including the bottom surface 61B may be formed to be narrower than other portions.

The field plate electrode 63 is surrounded by the insulating layer 21. The field plate electrode 63 may have a width less than that of the gate electrode 61. Due to a relatively small width of the field plate electrode 63, a thickness of the insulating layer 21 surrounding the field plate electrode 63 is relatively large. Thereby, electric field concentration within the gate trench 12 can be alleviated.

The gate electrode 61 may be located at a position such that the interface between the drift region 73 and the body region 74 is not lower than the bottom surface 61B of the gate electrode 61 along the Z-axis direction. The interface between the drift region 73 and the body region 74 may be aligned with the bottom surface 61B of the gate electrode 61 along the Z-axis direction, or may be located above the bottom surface 61B.

The gate electrode 61 and the field plate electrode 63 can be formed from conductive polysilicon, for example. The insulating layer 21 may include the gate insulating portion 21A interposed between the gate electrode 61 and the semiconductor layer 11 and covering the sidewall 12A of the gate trench 12. The gate electrode 61 and the semiconductor layer 11 are separated by the gate insulating portion 21A. When a predetermined gate voltage is applied to the gate electrode 61, a channel is formed in the p-type body region 74 adjacent to gate insulating portion 21A. The semiconductor device 10 can control the flow of electrons along the Z-axis direction between the n⁺ type source region 75 and the n-type drift region 73 via this channel.

The insulating layer 21 may further include a lower insulating portion 21B that covers the sidewall 12A and the bottom wall 12B of the gate trench 12 between the field plate electrode 63 and the semiconductor layer 11. The lower insulating portion 21B can be formed thicker than the gate insulating portion 21A on the sidewall 12A of the gate trench 12. In addition, the insulating layer 21 may further include an intermediate insulating portion 21C located between a top surface 63A of the field plate electrode 63 and the bottom surface 61B of the gate electrode 61.

### (Third and Fourth Gate Trenches)

As shown in FIG. 5, the gate trench 13 (the third gate trench 43 and the fourth gate trench 44) has an opening in the upper surface 11A of the semiconductor layer 11. The gate trench 13 has a depth along the Z-axis direction. The gate trench 13 extends through the source region 75 and the body region 74 of the semiconductor layer 11 to the drift region 73. The gate trench 13 has sidewalls 13A and bottom walls 13B. Bottom wall 13B is adjacent to the drift region 73. A depth D2 of the gate trench 13 may be between about 1 μm and about 10 μm. In one example, the depth D2 of the gate trench 13 may be equal to the depth D1 of the gate trench 12 shown in FIG. 4. Note that the depth D2 of the gate trench 13 may be different from the depth D1 of the gate trench 12.

As shown in FIG. 3, the gate trench 13 has a width along the Y-axis direction. The gate trench 13 extends along the X-axis direction. Therefore, the sidewalls 13A of the gate trench 13 face each other along the Y-axis direction. It can be said that the sidewall 13A of the gate trench 13 faces the Y-axis direction.

As shown in FIG. 5, the sidewall 13A of the gate trench 13 may or may not extend along a direction perpendicular to the upper surface 11A of the semiconductor layer 11 (Z-axis direction). In one example, the sidewall 13A may be inclined with respect to the Z-axis direction so that a trench width of the gate trench 13 becomes less toward the bottom wall 13B.

As shown in FIG. 3, the third gate trench 43 extends from the first gate trench 41 toward the second gate trench 42. The first gap 51 is formed between the third gate trench 43 and the second gate trench 42. The third gate trench 43 has an end sidewall 13C at a tip 43C spaced apart from the second gate trench 42. The end sidewall 13C faces the X-axis direction. The first gap 51 can be said to be a region between the end sidewall 13C of the third gate trench 43 and the sidewall 12A of the second gate trench 42. The end sidewall 13C may or may not extend along a direction perpendicular to the upper surface 11A of the semiconductor layer 11 (Z-axis direction). In one example, the end sidewall 13C may be inclined with respect to the Z-axis direction so that a length of the third gate trench 43 along the X-axis direction becomes shorter toward the bottom wall 13B.

The fourth gate trench 44 extends from the second gate trench 42 toward the first gate trench 41. The second gap 52 is formed between the fourth gate trench 44 and the first gate trench 41. The fourth gate trench 44 has an end sidewall 13C at a tip 44C that is spaced apart from the first gate trench 41. The end sidewall 13C faces the X-axis direction. The second gap 52 can be said to be a region between the end sidewall 13C of the third gate trench 43 and the sidewall 12A of the second gate trench 42. The end sidewall 13C may or may not extend along a direction perpendicular to the upper surface 11A of the semiconductor layer 11 (Z-axis direction). In one example, the end sidewall 13C may be inclined with respect to the Z-axis direction so that a length of the fourth gate trench 44 along the X-axis direction becomes shorter toward the bottom wall 13B.

The semiconductor device 10 can include the gate electrode 62 and the field plate electrode 64 arranged in the gate trench 13. The gate electrode 62 includes a top surface 62A covered with the insulating layer 21 and a bottom surface 62B opposite to the top surface 62A. The field plate electrode 64 is arranged in the gate trench 13 below the bottom surface 62B of the gate electrode 62 (between the bottom surface 62B of the gate electrode 62 and the bottom wall 13B of the gate trench 13). At least a portion of the bottom surface 62B of the gate electrode 62 faces the field plate electrode 64 with the insulating layer 21 in between.

The top surface 62A of the gate electrode 62 can be located below the upper surface 11A of the semiconductor layer 11. The bottom surface 62B and the top surface 62A of the gate electrode 62 may be flat or curved. The gate electrode 62 may or may not have a uniform width regardless of its position along the Z-axis direction. For example, the bottom portion of the gate electrode 62 including the bottom surface 62B may be formed to be narrower than other portions.

The field plate electrode 64 is surrounded by the insulating layer 21. The field plate electrode 64 may have a width less than that of the gate electrode 62. Due to a relatively small width of the field plate electrode 64, a thickness of the insulating layer 21 surrounding the field plate electrode 64 is relatively large. Thereby, electric field concentration within the gate trench 13 can be alleviated.

The gate electrode 62 may be located at such a position that the interface between the drift region 73 and the body region 74 is not lower than the bottom surface 62B of the gate electrode 62 along the Z-axis direction. The interface between the drift region 73 and the body region 74 may be aligned with the bottom surface 62B of the gate electrode 62 along the Z-axis direction, or may be located above the bottom surface 62B.

The gate electrode 62 and the field plate electrode 64 can be formed from conductive polysilicon, for example. The insulating layer 21 may include the gate insulating portion 21A interposed between the gate electrode 62 and the semiconductor layer 11 and covering the sidewall 13A of the gate trench 13. The gate electrode 62 and the semiconductor layer 11 are separated by the gate insulating portion 21A. When a predetermined gate voltage is applied to the gate electrode 62, a channel is formed in the p-type body region 74 adjacent to the gate insulating portion 21A. The semiconductor device 10 can control the flow of electrons along the Z-axis direction between the n⁺ type source region 75 and the n-type drift region 73 via this channel.

The insulating layer 21 may further include the lower insulating portion 21B that covers the sidewall 13A and the bottom wall 13B of the gate trench 13 between the field plate electrode 64 and the semiconductor layer 11. The lower insulating portion 21B can be formed thicker than the gate insulating portion 21A on the sidewall 13A of the gate trench 13. In addition, the insulating layer 21 may further include the intermediate insulating portion 21C located between a top surface 64A of the field plate electrode 64 and the bottom surface 62B of the gate electrode 62.

### (Field Plate Trench)

As shown in FIGS. 4 and 5, the field plate trench 14 has an opening in the upper surface 11A of the semiconductor layer 11. The field plate trench 14 has a depth along the Z-axis direction.

The field plate trench 14 extends through the source region 75 and the body region 74 of the semiconductor layer 11 to the drift region 73. The field plate trench 14 has sidewalls 14A and bottom walls 14B. The sidewall 14A is adjacent to the drift region 73. A depth D3 of the field plate trench 14 may be between about 1 μm and about 10 μm. In one example, the depth D3 of the field plate trench 14 may be equal to the depth D1 of the gate trench 12 or the depth D2 of the gate trench 13. Note that the depth D3 of the field plate trench 14 may be different from the depths D1 and D2 of the gate trenches 12 and 13.

The sidewall 14A of the field plate trench 14 may or may not extend along a direction perpendicular to the upper surface 11A of the semiconductor layer 11 (Z-axis direction). In one example, the sidewall 14A may be inclined with respect to the Z-axis direction so that a trench width of the field plate trench 14 becomes less toward the bottom wall 14B.

The field plate electrode 65 is arranged within the field plate trench 14. The field plate electrode 65 may be an electrode configured to receive a source voltage.

The field plate electrode 65 includes a top surface 65A covered with the insulating layer 21 and a bottom surface 65B opposite to the top surface 65A. The top surface 65A of the field plate electrode 65 can be located below the upper surface 11A of the semiconductor layer 11. The field plate electrode 65 is surrounded by the insulating layer 21.

The top surface 65A and the bottom surface 65B of the field plate electrode 65 may be flat or curved. Furthermore, the field plate electrode 65 may or may not have a uniform width regardless of its position along the Z-axis direction. For example, the field plate electrode 65 may have a smaller width closer to the bottom wall 14B of the field plate trench 14. Furthermore, the field plate electrode 65 may have a width less than that of the gate electrode 61. The field plate electrode 65 can be formed from conductive polysilicon, in one example.

As shown in FIGS. 4 and 5, the first contact 17A of the source contact plug 17 is configured to couple the field plate electrode 65 to the source electrode 32. As shown in FIG. 5, the first contact 17A extends through the insulating layer 21 between the top surface 65A of the field plate electrode 65 and the source electrode 32. Therefore, the field plate electrode 65 is electrically connected to the source electrode 32.

As shown in FIG. 3, the first contact 17A extends along the X-axis direction. As shown in FIG. 4, the first contact 17A extends from the field plate electrode 65 to the semiconductor layer 11. The first contact 17A is configured to couple the semiconductor layer 11 to the source electrode 32. The first contact 17A is in contact with the contact region 76 formed within the semiconductor layer 11.

As shown in FIG. 5, the second contact 17B of the source contact plug 17 is configured to couple the semiconductor layer 11 to the source electrode 32. The second contact 17B is in contact with the contact region 76 formed within the semiconductor layer 11. The second contact 17B can electrically connect the contact region 76 to the source electrode 32. The second contact 17B extends through the insulating layer 21 between the semiconductor layer 11 and the source electrode 32. The second contact 17B extends through the source region 75 in the semiconductor layer 11 to the body region 24.

The source electrode 32 is formed on the insulating layer 21. In the semiconductor device 10, the source electrode 32 is not formed directly on the source region 75 of the semiconductor layer 11, but is formed on the insulating layer 21. Therefore, the semiconductor device 10 has an advantage that it is less susceptible to voltage fluctuations in the source region 75.

The semiconductor device 10 can further include a drain electrode 33 formed on the lower surface 11B of the semiconductor layer 11. The drain electrode 33 is electrically connected to the drain region 71. The drain electrode 33 can be formed from at least one of Ti, Ni, Au, Ag, Cu, Al, Cu alloy, and Al alloy.

### (Effect)

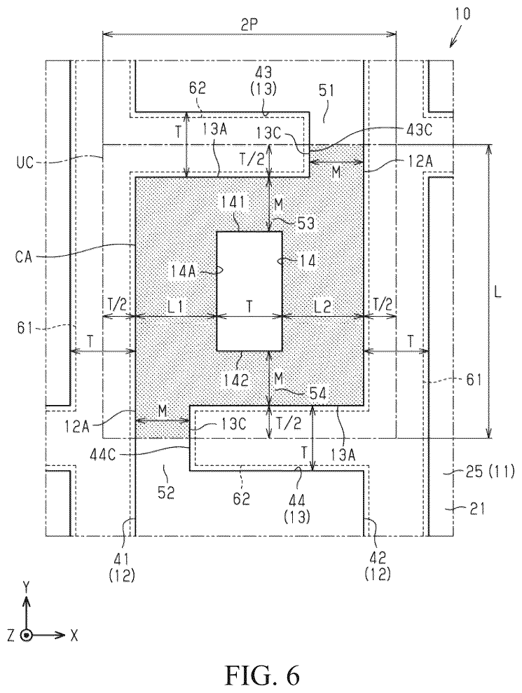

Next, an operation of the semiconductor device 10 will be explained. FIG. 6 is a schematic plan view showing a portion of the semiconductor device 10 and shows one unit cell UC. In FIG. 6, the semiconductor layer 11 (the cell area CA) included in the unit cell UC is hatched to make it easier to understand.

The semiconductor device 10 includes the third gate trench 43 extending from the first gate trench 41 toward the second gate trench 42, and the fourth gate trench 44 extending from the second gate trench 42 toward the first gate trench 41. The third gate trench 43 forms the first gap 51 with the second gate trench 42, and the fourth gate trench 44 forms the second gap 52 with the first gate trench 41.

As shown in FIGS. 3 to 5, the semiconductor device 10 includes the gate electrode 61 disposed within the first gate trench 41 and the second gate trench 42, and the gate electrode 62 arranged in the third gate trench 43 and the fourth gate trench 44. As shown in FIG. 4, the gate electrode 61 faces the semiconductor layer 11 with the insulating layer 21 (the gate insulating portion 21A) in the first and second gate trenches 41 and 42 interposed therebetween. As shown in FIG. 5, the gate electrode 62 faces the semiconductor layer 11 with the insulating layer 21 (the gate insulating portion 21A) in the third and fourth gate trenches 43 and 44 interposed therebetween.

When a predetermined gate voltage is applied to the gate electrodes 61 and 62, a channel is formed in the body region 74 adjacent to the gate insulating portion 21A. A channel is formed along the sidewalls 12A of the first gate trench 41 and the second gate trench 42 in the semiconductor layer 11 forming the sidewalls 12A. Furthermore, a channel is formed along the sidewalls 13A and end sidewalls 13C of the third gate trench 43 and the fourth gate trench 44 in the semiconductor layer 11 forming the sidewalls 13A and the end sidewalls 13C.

### Comparative Example

Here, the number of current paths and the cross-sectional area of current paths in the semiconductor device 10 will be explained with reference to a comparative example.

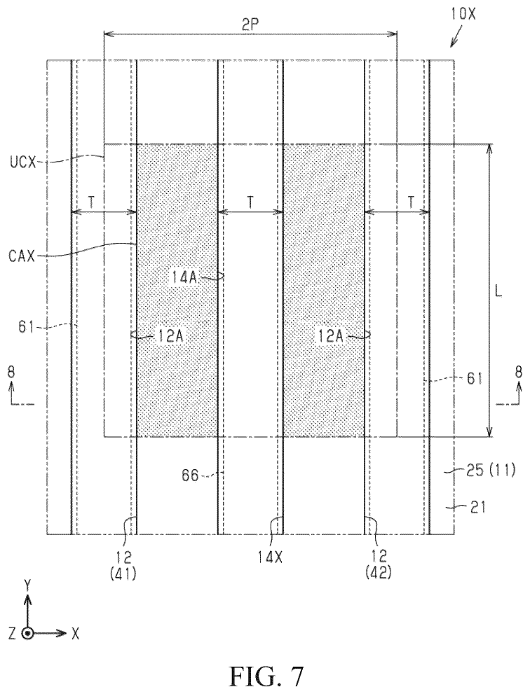

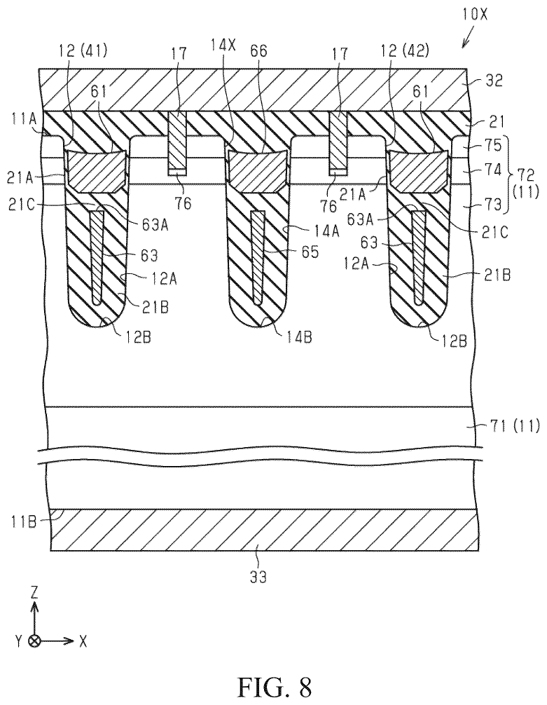

FIG. 7 shows a portion of a semiconductor device 10X of a comparative example. FIG. 8 shows a cross-sectional view taken along line 8-8 in FIG. In FIGS. 7 and 8, components similar to those of the semiconductor device 10 are given the same reference numerals. Furthermore, detailed description of the same components as those of the semiconductor device 10 will be omitted.

In FIG. 7, the source contact plug 17 is omitted. FIG. 7 shows a unit cell UCX of the same size as the unit cell UC of the semiconductor device 10 shown in FIG. Furthermore, in FIG. 7, the cell area CAX (the semiconductor layer 11) of the unit cell UCX of the semiconductor device 10X of the comparative example is hatched.

The semiconductor device 10X of the comparative example does not include the third gate trench 43 and the fourth gate trench 44 shown in FIG. 6. Furthermore, in the semiconductor device 10X of the comparative example, a field plate trench 14X extends continuously along the Y-axis direction similarly to the gate trench 12 (the first gate trench 41, the second gate trench 42). Therefore, in the semiconductor device 10X of the comparative example, the gate trenches 12 and field plate trenches 14X are alternately arranged along the X-axis direction. The gate electrode 61 buried in the insulating layer 21 is arranged in the gate trench 12. A buried electrode 66 buried in the insulating layer 21 is arranged in the field plate trench 14X.

Here, for ease of understanding, in the semiconductor device 10 of the present embodiment and the semiconductor device 10X of the comparative example, the trench width of each gate trench 12, 13 (first to fourth gate trenches 41 to 43) and the field plate trench 14 are set to be “T”. Furthermore, lengths of the first to fourth gaps 51 to 54 in the semiconductor device 10 of this embodiment are set to be “M”. Furthermore, the trench widths of the gate trenches 12 (41, 42) and the field plate trenches 14X in the semiconductor device 10X of the comparative example are set to be “T”.

In the semiconductor device 10X of the comparative example, a channel is formed in the semiconductor layer 11 along the sidewall 12A of the gate trench 12. A length of the channel included in one unit cell in the plan view is obtained by the length L of the unit cell UCX along the Y-axis direction in which the two gate trenches 12 extend. In the plan view, the length of the portion where the channel is formed, that is, the length of the sidewall of the gate trench in which the gate electrode is arranged, is referred to as the number of current paths CPn. The number of current paths CPnX in the semiconductor device 10X of the comparative example is CPnX=2L.

On the other hand, the number of current paths CPn in the semiconductor device 10 of this embodiment is obtained by lengths of the side walls 12A and 13A of the first to fourth gate trenches 41 to 44 included in the unit cell UC and a length of end side wall 13C of the third gate trench 43 and the fourth gate trench 44. Along the Y-axis direction, a sum of the length of the sidewall 12A of the first gate trench 41 and the length of the end sidewall 13C of the third gate trench 43 is “2L”. Along the X-axis direction, the length of the sidewall 12A of the third gate trench 43 is a value “2P−T−M” obtained by subtracting the trench width “2T/2” of the first and second gate trenches 41 and 42 included in the unit cell UC and the length “M” of the first gap 51 from the arranged pitch “2P” of the first and second gate trenches 41 and 42. Therefore, the number of current paths CPn in the semiconductor device 10 of this embodiment is CPn=2L+2 (2P−T−M).

The semiconductor device 10 of this embodiment sets the trench widths of the first to fourth gate trenches 41 to 44 and lengths of the first and second gaps 51 and 52 by a difference between the current path number CPn and the current path number CPnX of the semiconductor device 10X of the comparative example being a positive value, that is, 2 (2P−T−M)>0. That is, the length M of the first gap 51 and the second gap 52 is set to be less than a difference (=2P−T) between the arranged pitch 2P of the first gate trench 41 and the second gate trench 42, and the trench width T of the first gate trench 41 and the second gate trench 42 (M<2P−T). Therefore, the area where channels are formed can be increased without narrowing the number of current paths CPn in the semiconductor device 10 of this embodiment, that is, the arranged pitch 2P of the gate trenches 12 (the first and second gate trenches 41, 42) in the semiconductor layer 11. As a result, an on-resistance of the semiconductor device 10 can be reduced.

In the semiconductor device 10, a current flows between the source region 75 and the drain region 71 along the Z-axis direction. In the plan view from the Z-axis direction, the semiconductor layer 11 included in the unit cell UC becomes a region in the semiconductor device 10 through which current flows. Therefore, the area of the semiconductor layer 11 becomes the cross-sectional area of the current flowing along the Z-axis direction in the semiconductor device 10. A cross-sectional area of this current is defined as a current path cross-sectional area CPa. The greater the current path cross-sectional area CPa is, the more current will flow.

In the semiconductor device 10X of the comparative example, the current path cross-sectional area CPa is obtained by multiplying the distance between the gate trench 12 and the field plate trench 14X by the length of the unit cell UC along the Y-axis direction. Therefore, a current path cross-sectional area CPaX in the semiconductor device 10X of the comparative example is CPaX=2L (P−T).

On the other hand, the current path cross-sectional area CPa in the semiconductor device 10 of this embodiment is obtained by a sum of an area of the region from the first and second gate trenches 41 and 42 to the field plate trench 14 and an area of the first to fourth gaps 51 to 54 in the plan view. Therefore, the current path cross-sectional area CPa in the semiconductor device 10 of this embodiment is CPa=3MT+2(P−T)(L−T).

The semiconductor device 10 of this embodiment sets the trench widths of the first to fourth gate trenches 41 to 44 and the lengths of the first to fourth gaps 51 to 54 by a difference between the current path cross-sectional area CPa and the current path cross-sectional area CPaX of the semiconductor device 10X of the comparative example being a positive value, that is, T (3M−2(P−T))>0. That is, the length M of the first to fourth gaps 51 to 54 is set to be greater than ⅔ of a difference (=P−T) between the arranged pitch P of the first and second gate trenches 41, 42 and the field plate trench 14, and the trench width T of the first and second gate trenches 41, 42 and the field plate trench 14 (M>2(P−T)/3). Therefore, the current path cross-sectional area CPa in the semiconductor device 10 of this embodiment, that is, the area of the semiconductor layer 11 through which the current flows can be increased.

In the semiconductor device 10X of the comparative example, reducing the pitch of the gate trenches 12 by reducing the width of the gate trenches 12 can be considered to reduce the on-resistance. In this case, the on-resistance is reduced by increasing the number of current paths CPn. In this method, since the number of the gate trenches 12 increases for the same chip size, the current path cross-sectional area CPa decreases, and the amount of current between the source and drain decreases. In contrast, the semiconductor device 10 of the present embodiment can increase the number of current paths CPn at the same arranged pitch as the semiconductor device 10X of the comparative example. Furthermore, the semiconductor device 10 of this embodiment can increase the current path cross-sectional area CPa compared to the semiconductor device 10X of the comparative example. Therefore, the semiconductor device 10 of this embodiment can secure the amount of current and reduce the on-resistance.

In the semiconductor device 10 of this embodiment, the field plate trench 14 is separated from the third gate trench 43 along the Y-axis direction. The third gap 53 is formed between the field plate trench 14 and the third gate trench 43. Furthermore, the field plate trench 14 is spaced apart from the fourth gate trench 44 along the Y-axis direction. The fourth gap 54 is formed between the field plate trench 14 and the fourth gate trench 44. The length M of the third gap 53 and the fourth gap 54 is preferably less than the distance L1 (L2) between the first gate trench 41 (second gate trench 42) and the field plate trench 14. Thereby, electric field concentration can be alleviated.

As described above, according to this embodiment, the following effects are achieved. (1) The semiconductor device 10 includes: a semiconductor layer 11, including an upper surface 11A; a first gate trench 41 and a second gate trench 42, disposed in the semiconductor layer 11, arranged along the X-axis direction in a plan view seen from a direction perpendicular to the upper surface 11A, and extending along the Y-axis direction intersecting the X-axis direction; a third gate trench 43, extending along the X-axis direction from the first gate trench 41 toward the second gate trench 42 and forming a first gap 51 with the second gate trench 42; a fourth gate trench 44, spaced apart from the third gate trench 43 along the Y-axis direction, extending along the X-axis direction from the second gate trench 42 toward the first gate trench 41 and forming a second gap 52 with the first gate trench 41; a field plate trench 14, disposed in a cell area CA surrounded by the first to fourth gate trenches 41 to 44; gate electrodes 61 and 62, disposed within the first to fourth gate trenches 41 to 44; an insulating layer 21, disposed on the semiconductor layer 11; a source electrode 32, disposed on the insulating layer 21; and a field plate electrode 65, arranged in the field plate trench 14 and electrically connected to the source electrode 32.

According to this configuration, the semiconductor device 10 can increase the area of the channel formed in the semiconductor layer 11. Therefore, it is possible to reduce the on-resistance of the semiconductor device 10.
(2) The length M of the first gap 51 and the second gap 52 is set to be less than a difference (=2P−T) between the arranged pitch 2P of the first gate trench 41 and the second gate trench 42, and the trench width T of the first gate trench 41 and the second gate trench 42 (M<2P−T). Thereby, the number of current paths CPn in the semiconductor device 10 of this embodiment, that is, the region in which a channel is formed in the semiconductor layer 11 can be increased. Thereby, the on-resistance of the semiconductor device 10 can be reduced.
(3) The length M of the first to fourth gaps 51 to 54 is set to be greater than ⅔ of a difference (=P−T) between the arranged pitch P of the first and second gate trenches 41, 42 and the field plate trench 14, and the trench width T of the first and second gate trenches 41, 42 and the field plate trench 14 (M>2(P−T)/3). Thereby, the current path cross-sectional area CPa in the semiconductor device 10 of this embodiment, that is, the area of the semiconductor layer 11 through which the current flows can be increased.
(4) The semiconductor device 10 of this embodiment can increase the number of current paths CPn at the same arranged pitch as the semiconductor device 10X of the comparative example. Furthermore, the semiconductor device 10 of this embodiment can increase the current path cross-sectional area CPa compared to the semiconductor device 10X of the comparative example. Therefore, the semiconductor device 10 of this embodiment can secure the amount of current and reduce the on-resistance.
(5) The field plate trench 14 is separated from third gate trench 43 along the Y-axis direction. The third gap 53 is formed between the field plate trench 14 and the third gate trench 43. Furthermore, the field plate trench 14 is spaced apart from the fourth gate trench 44 along the Y-axis direction. The fourth gap 54 is formed between the field plate trench 14 and the fourth gate trench 44. The length M of the third gap 53 and the fourth gap 54 is preferably less than the distance L1 (L2) between the first gate trench 41 (second gate trench 42) and the field plate trench 14. Thereby, electric field concentration can be alleviated.

### MODIFIED EXAMPLES

The above embodiment can be modified as follows, for example. The above embodiment and each modified example below can be combined with each other as long as no technical contradiction occurs. In addition, in the following modified examples, parts common to the above embodiment are given the same reference numerals as in the above embodiment, and the explanation thereof will be omitted.

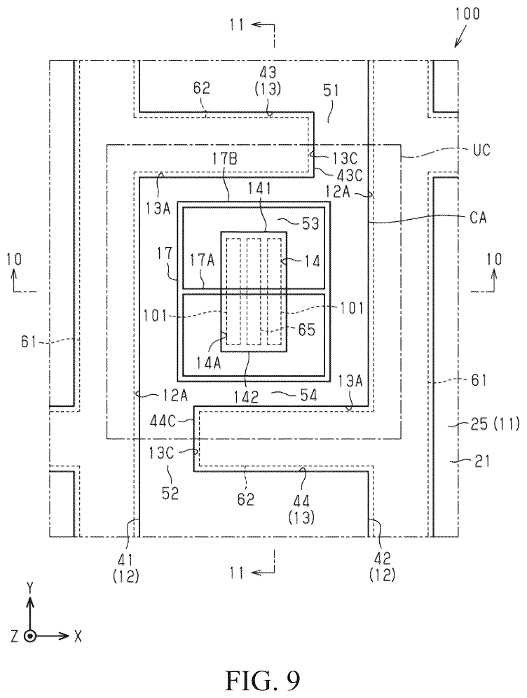

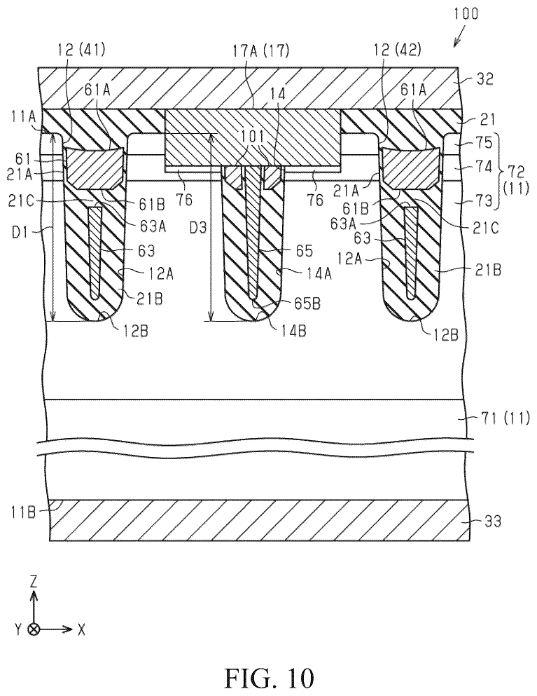

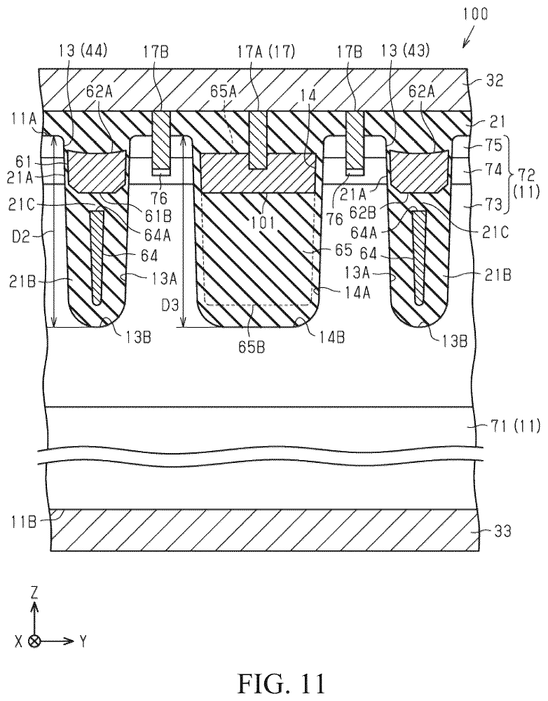

FIG. 9 is a schematic plan view showing an enlarged portion of the semiconductor device 100 of the modified example, and shows a region including one unit cell UC. FIG. 10 is a schematic cross-sectional view taken along line 10-10 in FIG. 9. FIG. 11 is a schematic cross-sectional view taken along line 11-11 in FIG. 9.

The semiconductor device 100 of the modified example may include a second field plate electrode 101 disposed within the field plate trench 14. The second field plate electrode 101 is arranged on both sides of the field plate electrode 65 along the X-axis direction. The second field plate electrode 101 is arranged to sandwich the field plate electrode 65. The second field plate electrode 101 is spaced apart from the field plate electrode 65 along the X-axis direction. Note that the second field plate electrode 101 may be in contact with the field plate electrode 65. In one example, the second field plate electrode 101 can be formed from conductive polysilicon. The second field plate electrode 101 may be arranged at the same position as the gate electrode 61 along the Z-axis direction. The second field plate electrode 101 is surrounded by the insulating layer 21.

The second field plate electrode 101 may be electrically connected to the source electrode 32 by the source contact plug 17. Local electric field concentration in the semiconductor layer 11 around the field plate trench 14 can be further alleviated by arranging the second field plate electrode 101 electrically connected to the source electrode 32 within the field plate trench 14.

In the semiconductor device 10 of the above embodiment, the third gate trenches 43 extending from each gate trench 12 are arranged at the same position along the Y-axis direction. Similarly, the fourth gate trenches 44 extending from each gate trench 12 are arranged at the same position along the Y-axis direction. On the other hand, the arrangement positions of the third gate trench 43 and the fourth gate trench 44 may be changed as appropriate.

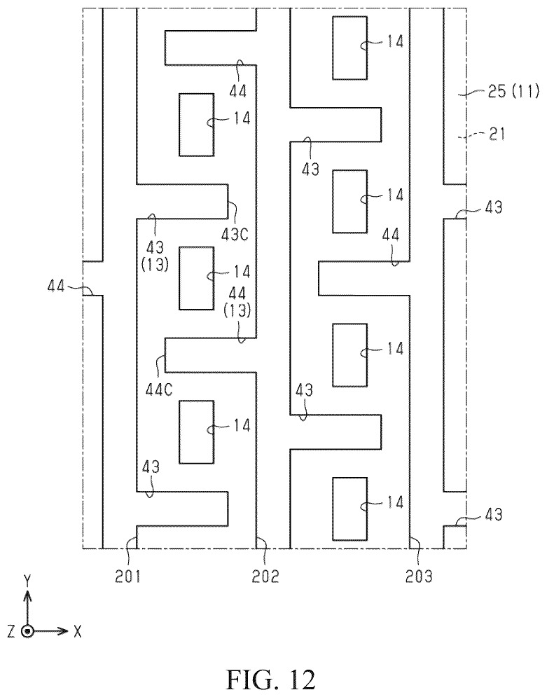

As shown in FIG. 12, positions of the third gate trenches 43 extending from gate trenches 201 and 202 toward adjacent gate trenches 202 and 203 may be different along the Y-axis direction. For example, the position of the third gate trench 43 extending from the gate trench 201 may be aligned with the field plate trench 14 between the gate trench 201 and the gate trench 202. Similarly, positions of the fourth gate trenches 44 extending from the gate trenches 202 and 203 toward the adjacent gate trenches 201 and 202 may be different along the Y-axis direction. For example, the position of the fourth gate trench 44 extending from the gate trenches 202, 203 toward the adjacent gate trenches 201, 202 may be aligned with the field plate trench 14 between the gate trench 202 and the gate trench 203.

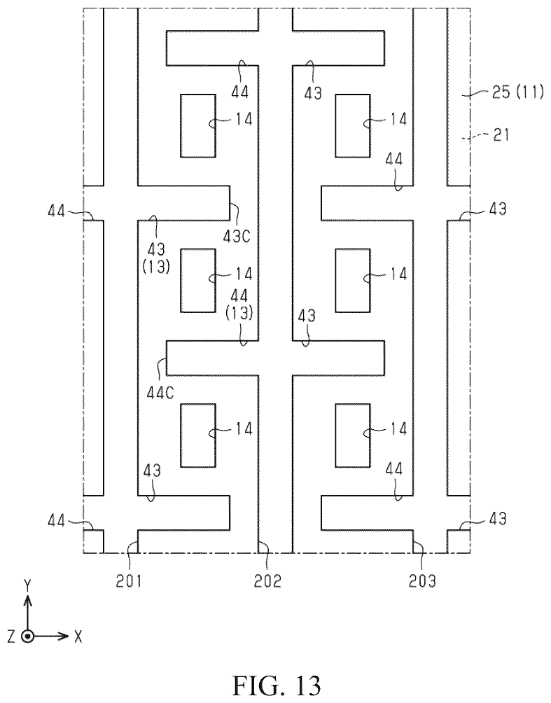

As shown in FIG. 13, for one gate trench 202, the third gate trench 43 extending toward the adjacent gate trench 203 and the fourth gate trench 44 extending toward the adjacent gate trench 201 may be arranged at the same position along the Y-axis direction. The same can be applied to the gate trenches 201 and 203.

As used in the present disclosure, the term “on” includes both “on” and “above” unless the context clearly indicates otherwise. Thus, although the phrase “the first layer is formed on the second layer” refers to the fact that in some embodiments the first layer may be disposed directly on the second layer in contact with the second layer, it is intended that in other embodiments the first layer may be disposed above the second layer without contacting the second layer. That is, the term “on” does not exclude structures in which other layers are formed between the first layer and the second layer.

The Z-axis direction used in the present disclosure does not necessarily need to be a vertical direction, nor does it need to completely coincide with the vertical direction. Accordingly, in various structures according to the present disclosure (e.g., the structure shown in FIG. 1), “upper” and “lower” along the Z-axis direction described in this specification are not limited to “upper” and “lower” along the vertical direction. For example, the X-axis direction may be a vertical direction, or the Y-axis direction may be a vertical direction.

The technical ideas that can be understood from this disclosure are described below. Note that, not for the purpose of limitation but for the purpose of aiding understanding, the reference numerals of the corresponding components in the embodiments are attached to the components described in the supplementary notes. The reference numerals are shown by way of example to aid understanding, and the components described in each appendix should not be limited to the components indicated by the reference numerals.

### (Note 1)

A semiconductor device, comprising:

a semiconductor layer (11), including an upper surface (11A);

a first gate trench (41) and a second gate trench (42), disposed in the semiconductor layer (11), arranged along a first direction (X) in a plan view seen from a direction perpendicular to the upper surface (11A), and extending along a second direction (Y) intersecting the first direction (X);

a third gate trench (43), extending along the first direction (X) from the first gate trench (41) toward the second gate trench (42) and forming a first gap (51) with the second gate trench (42);

a fourth gate trench (44), spaced apart from the third gate trench (43) along the second direction (Y), extending along the first direction (X) from the second gate trench (42) toward the first gate trench (41) and forming a second gap (52) with the first gate trench (41);

a field plate trench (14), disposed in a cell region surrounded by the first to fourth gate trenches (41 to 44);

gate electrodes (61 and 62), disposed within the first to fourth gate trenches (41 to 44);

an insulating layer (21), formed on the semiconductor layer (11);

a source electrode (32), formed on the insulating layer (21); and

a field plate electrode (65), arranged in the field plate trench (14) and electrically connected to the source electrode (32).

### (Note 2)

The semiconductor device of Note 1, wherein arranged pitches (P) of the first gate trench (41), the field plate trench (14) and the second gate trench (42) along the first direction (X) are substantially equal.

### (Note 3)

The semiconductor device of Note 1 or 2, wherein a second length (M, M2) of the second gap (52) along the first direction is substantially equal to a first length (M, M1) of the first gap (51) along the first direction (X).

### (Note 4)

The semiconductor device of Note 3, wherein along the first direction (X), a first length (M) of the first gap (51) between the third gate trench (43) and the second gate trench (42) is substantially less than a difference between an arranged pitch (2P) of the first gate trench (41) and the second gate trench (42), and a trench width (T) of the first and second gate trenches (41, 42) (M<2P−T).

### (Note 5)

The semiconductor device of Note 4, wherein the first length (M) of the first gap (51) is substantially greater than ⅔ of the difference between an arranged pitch (P) of the first gate trench (41) and the field plate trench (14), and the trench width (T) (M>2(P−T)/3).

### (Note 6)

The semiconductor device of any one of Notes 1 to 5, wherein along the second direction (Y), a third length (M, M3) of a third gap (53) between the field plate trench (14) and the third gate trench (43) is substantially equal to a fourth length (M, M4) of a fourth gap (54) between the field plate trench (14) and the fourth gate trench (44).

### (Note 7)

The semiconductor device of Note 6, wherein the third length (M3) of the third gap (53) is substantially equal to the first length (M1) of the first gap (51).

### (Note 8)

The semiconductor device of any one of Notes 1 to 7, wherein a trench width (T1) of the first and second gate trenches (41, 42) along the first direction (X) is substantially equal to a trench width (T2) of the third and fourth gate trenches (43, 44) along the second direction (Y).

### (Note 9)

The semiconductor device of any one of Notes 1 to 8, wherein a trench width (T, T3) of the field plate trench (14) along the first direction (X), a trench width (T, T1) of the first and second gate trenches (41, 42) along the first direction (X) and a trench width (T, T2) of the third and fourth gate trenches (43, 44) along the second direction (Y) are equal.

### (Note 10)

The semiconductor device of any one of Notes 1 to 9, wherein

an arranged pitch (L) of the third and fourth gate trenches (43, 44) along the second direction (Y) is equal to

an arranged pitch (2P) of the first and second gate trenches (41, 42) along the first direction (X) (L=2P).

### (Note 11)

The semiconductor device of any one of Notes 1 to 10, further comprising a source contact plug (17) electrically connecting the source electrode (32) and the field plate electrode (65).

### (Note 12)

The semiconductor device of Note 11, wherein

the source contact plug (17) includes:
a first contact portion (17A), extending to intersect the field plate trench (14) in the plan view; and
a second contact portion (17B), formed surrounding the field plate trench (14) and connected to both ends of the first contact portion (17A), wherein

the field plate electrode (65) is electrically connected to the first contact portion (17A).

### (Note 13)

The semiconductor device of Note 11 or 12, further comprising a second field plate electrode (101) disposed within the field plate trench (14) so as to sandwich the field plate electrode (65) along the first direction (X).

### (Note 14)

The semiconductor device of Note 13, wherein the second field plate electrode (101) is electrically connected to the source contact plug (17).

The above description is merely illustrative. Those skilled in the art will recognize that many more possible combinations and permutations are possible beyond those listed for the purpose of describing the techniques of the present disclosure. The present disclosure is intended to cover all alternatives, variations, and modifications falling within the scope of this disclosure, including the claims.

1. A semiconductor device, comprising:
a semiconductor layer, including an upper surface;
a first gate trench and a second gate trench, disposed in the semiconductor layer, arranged along a first direction in a plan view seen from a direction perpendicular to the upper surface, and extending along a second direction intersecting the first direction;
a third gate trench, extending along the first direction from the first gate trench toward the second gate trench and forming a first gap with the second gate trench;
a fourth gate trench, spaced apart from the third gate trench along the second direction, extending along the first direction from the second gate trench toward the first gate trench and forming a second gap with the first gate trench;
a field plate trench, disposed in a cell region surrounded by the first to fourth gate trenches;
gate electrodes, disposed within the first to fourth gate trenches;
an insulating layer, formed on the semiconductor layer;
a source electrode, formed on the insulating layer; and
a field plate electrode, arranged in the field plate trench and electrically connected to the source electrode.

2. The semiconductor device of claim 1, wherein arranged pitches of the first gate trench, the field plate trench and the second gate trench along the first direction are substantially equal.

3. The semiconductor device of claim 1, wherein a second length of the second gap along the first direction is substantially equal to a first length of the first gap along the first direction.

4. The semiconductor device of claim 2, wherein a second length of the second gap along the first direction is substantially equal to a first length of the first gap along the first direction.

5. The semiconductor device of claim 3, wherein along the first direction, a first length of the first gap between the third gate trench and the second gate trench is substantially less than a difference between
an arranged pitch of the first gate trench and the second gate trench, and
a trench width of the first and second gate trenches.

6. The semiconductor device of claim 4, wherein along the first direction, a first length of the first gap between the third gate trench and the second gate trench is substantially less than a difference between
an arranged pitch of the first gate trench and the second gate trench, and
a trench width of the first and second gate trenches.

7. The semiconductor device of claim 5, wherein the first length of the first gap is substantially greater than ⅔ of the difference between
an arranged pitch of the first gate trench and the field plate trench, and the trench width.

8. The semiconductor device of claim 6, wherein the first length of the first gap is substantially greater than ⅔ of the difference between
an arranged pitch of the first gate trench and the field plate trench, and the trench width.

9. The semiconductor device of claim 1, wherein along the second direction, a third length of a third gap between the field plate trench and the third gate trench is substantially equal to a fourth length of a fourth gap between the field plate trench and the fourth gate trench.

10. The semiconductor device of claim 9, wherein the third length of the third gap is substantially equal to the first length of the first gap.

11. The semiconductor device of claim 1, wherein
a trench width of the first and second gate trenches along the first direction is substantially equal to
a trench width of the third and fourth gate trenches along the second direction.

12. The semiconductor device of claim 1, wherein
a trench width of the field plate trench along the first direction,
a trench width of the first and second gate trenches along the first direction and
a trench width of the third and fourth gate trenches along the second direction are equal.

13. The semiconductor device of claim 1, wherein
an arranged pitch of the third and fourth gate trenches along the second direction is equal to
an arranged pitch of the first and second gate trenches along the first direction.

14. The semiconductor device of claim 1, further comprising a source contact plug electrically connecting the source electrode and the field plate electrode.

15. The semiconductor device of claim 14, wherein
the source contact plug includes:
a first contact portion, extending to intersect the field plate trench in the plan view; and
a second contact portion, formed surrounding the field plate trench and connected to both ends of the first contact portion, wherein
the field plate electrode is electrically connected to the first contact portion.

16. The semiconductor device of claim 14, further comprising a second field plate electrode disposed within the field plate trench so as to sandwich the field plate electrode along the first direction.

17. The semiconductor device of claim 15, further comprising a second field plate electrode disposed within the field plate trench so as to sandwich the field plate electrode along the first direction.

18. The semiconductor device of claim 16, wherein the second field plate electrode is electrically connected to the source contact plug.

19. The semiconductor device of claim 17, wherein the second field plate electrode is electrically connected to the source contact plug.
